(19) United States
(12) Patent Application Publication
(10) Pub. No.: US 2010/0250161 A1
(43) Pub. Date: Sep. 30, 2010

(54) Monitoring system for collection and distribution of a power consumption information

(76) Inventors: Eugene Wang, Palo Alto, CA (US); David Moss, Tucson, AZ (US)

Correspondence Address: EUGENE WANG, 620 Lowell Ave, Palo Alto, CA, 94301, US

(21) Appl. No.: 12/383,943

(22) Filed: Mar. 30, 2009

(51) Int. Cl. G01R 21/00; G06F 15/16; G06F 19/00

(52) U.S. Cl. 702/62; 709/217

(57) ABSTRACT

A monitoring system for collection and distribution of power consumption information. It comprises a first monitoring device that is employed between, and electrically coupled to, a power socket and a first electrical appliance. The monitoring system also comprises a collector device that collects an energy consumption data from the first monitoring device and communicates it to a remote server. The collector device receives monitoring data from a number of electrical appliances with which it is communicatively coupled. Communication between the collector device that receives monitoring data from a number of electrical appliances and the monitoring devices occurs over a power line.

### CROSS REFERENCES TO RELATED APPLICATIONS

### BACKGROUND

1. Technical Field

The present invention relates generally to energy saving and power consumption monitoring and particularly to a solution wherein power consumption by individual appliances and devices are monitored and reported.

2. Related Art

Power consuming appliances are becoming ubiquitous. People use electrical tools and appliances all over their residences. Some electrical appliances are turned on and seldom turned off, even when the user does not need the appliance or make use of it. Most people living in a modern house have a TV, a refrigerator, a washing machine, a washer, a dryer, a heating system, an air conditioner, etc. Most of these devices consume a lot of power when they are plugged into power outlets, some even when they are not being used.

Every day people use a lot of electricity for running electrical tools and appliances but they don't know which appliances are consuming how much power. Every month people get an electric bill and they would like to lower it, but they do not know how to reduce their monthly electrical bill. Every year mankind adds to global warming but we do not individually have an easy way to help reduce global warming. People do not seem to be able to control power consumption at their homes and work places.

Unfortunately, despite widespread acceptance of green house effects and despite rise in the price of crude oil, people have not been provided with effective power saving technologies. People are being encouraged to turn off light bulbs when they are not in a room. Some appliance can be turned off if they are not being used. However, turning off a refrigerator when a user is travelling it is not an option as food stored in the refrigerator is likely to get spoiled when it is turned off.

Often people do not know how much power they can save by following all the recommended power saving recommendations. Well meaning individuals have no idea how effective all their power saving efforts has been. Even if one were to use green electrical appliances, one does not know if one can be more effective in saving power by adopting better usage patterns.

In view of the foregoing considerations, it is clear that there is a need for an improved system and method for measuring power consumption and monitoring power usage.

### BRIEF SUMMARY OF THE INVENTION

The present invention is directed to apparatus and methods of operation that are further described in the following Brief Description of the Drawings, the Detailed Description of the Invention, and the claims. Other features and advantages of the present invention will become apparent from the following detailed description of the invention made with reference to the accompanying drawings.

### BRIEF DESCRIPTION OF THE DRAWINGS

FIG. 1 is a perspective block diagram of a monitoring system for collection and distribution of power consumption information that is collected from a plurality of electrical appliances in a premises.

FIG. 2 is a method of operating the monitoring system for collection and distribution of power consumption information wherein the collector device monitors energy consumption by individual electrical appliances employing the monitoring devices for monitoring purposes.

FIG. 3 is an exemplary system for monitoring and reporting power consumption within a premises.

### DETAILED DESCRIPTION OF THE DRAWINGS

The present invention provides an elegant means of monitoring power consumption of individual appliances in a residence or building wherein the power consumption is monitored by the use of new and innovative monitoring devices built in accordance with the present invention. Power consumption information is collected by a collector device that is communicated to a remote server.

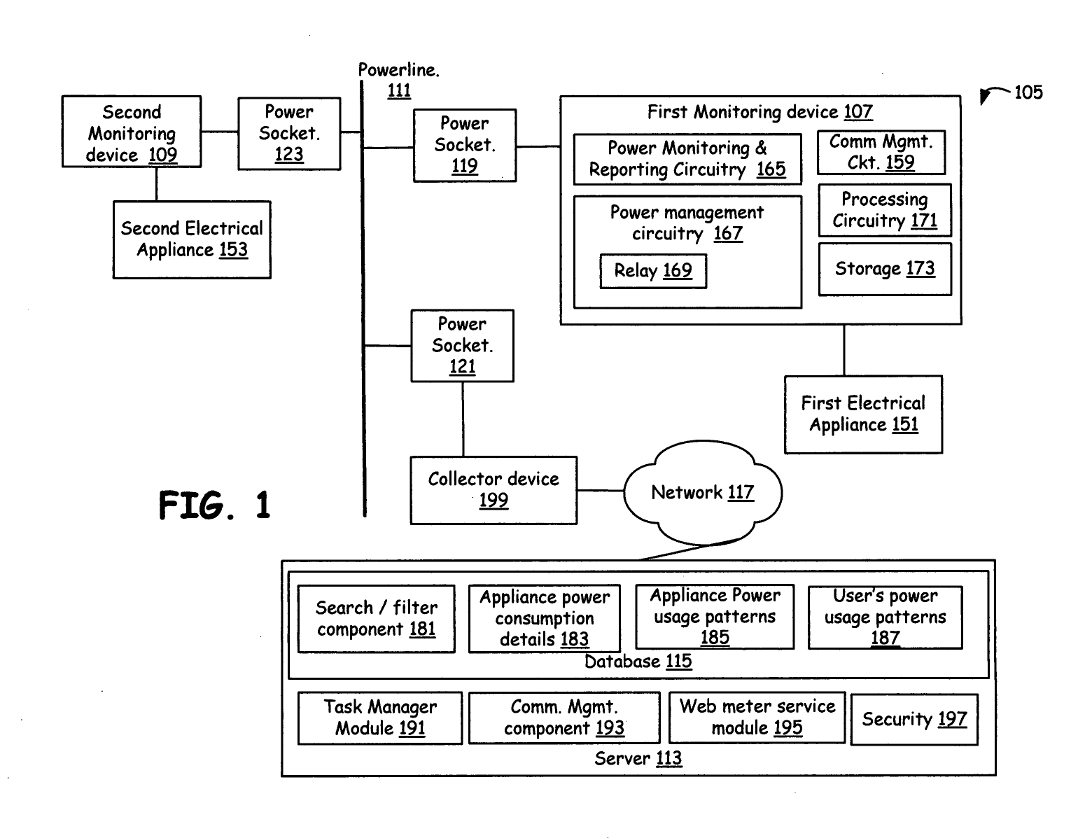

FIG. 1 is a perspective block diagram of a monitoring system 105 for collection and distribution of a power consumption information that is collected from a plurality of electrical appliances 151, 153 in a premises. The monitoring system 105 for collection and distribution of a power consumption information comprises a first monitoring device that is employed between, and electrically coupled to, a power socket 119 and a first electrical appliance 151. The monitoring system 105 also comprises a collector device 199 that collects an energy consumption data from the first monitoring device 107 and communicates it to a remote server 113. The collector device 199 receives monitoring data from a number of electrical appliances 151, 153 with which it is communicatively coupled. Communication between the collector device 199 that receives monitoring data from a number of electrical appliances 151, 153, and the monitoring devices 107, 109, occurs over a power line 111. Other means of communication such as Bluetooth and WiFi are also contemplated in some embodiments.

The first monitoring device 107 monitors the energy consumption by the first electrical appliance 151 and communicates the energy consumption data to the collector device 199 over a first communication means, such as communication over the powerline 111. The collector device 199 processes the energy consumption data and subsequently communicates it to the remote server 113. Such communication between the collector device 199 and the remote server 113 occurs over a network 117. In one embodiment, the network 117 is Internet.

The first communication means is often a powerline 111 to which both the first monitoring device 107 and the collector device 199 are communicatively and electrically coupled. Communications over the powerline 111 occurs by impressing a modulated carrier signal on the wiring system used to provide power within the premises. The powerline 111 is used to provide one or more types of powerline communications using different frequency bands, depending on the signal transmission characteristics of the power wiring used. Most power wiring system within a were originally intended for transmission of AC power and therefore have only a limited ability to carry higher frequencies for communication. Data transfer over the powerline 111 occurs, in one embodiment, over a low-frequency (about 100-200 kHz) carrier impressed the powerline 111. In a different embodiment, a higher data rate is employed that provides a local area network operating at millions of bits per second. In a related embodiment, the powerline 111 is used to implement a home network employing a technology that corresponds to one of the specifications provided by the HomePlug Powerline Alliance, the Universal Powerline Association, the HD-PLC Alliance or Broadband over Powerlines (BPL).

The first monitoring device 107 comprises a power monitoring and reporting circuitry 165 that monitors power consumption by the first electrical appliance 151, a power management circuitry 167 that facilitates turning power off, power on, operating a relay 169, etc. The relay 169 is employed selectively to cut power consumed by the first electrical appliance 151. The first monitoring device 107 also comprises a communication management circuitry 159 that facilitates powerline 111 communications, a processing circuitry 171 that facilitates executing code and managing tasks, and a storage 173 that is used to store power consumption data collected from the first electrical appliance 151, store commands received from or via the collector device 199, etc.

In general, the monitoring system 105 provides one or more modes of information transfer between the first monitoring device 107 and the collector device 199. For example, in one mode, the first monitoring device 107 starts out sending power consumption data rapidly to the collector device 199 when the associated appliance, such as the first electrical appliance 151, is first turned on, and then tapers off as a quiescent state is reached. When an event occurs, such as a reporting event triggered in or communicated to the first monitoring device 107, the first monitoring device 107 starts communicating data to the collector device 199 rapidly initially and then tapering off after reaching a steady state. In addition, the collector device 199 is capable of asynchronously gathering energy consumption data from the first monitoring device 107 and storing it locally until it subsequently transfers it over the network 117 to the server 113 employing an appropriate format. Such a format is an efficient encoded format in one related embodiment and an XML based format in another.

Other modes are supported, wherein power consumption data is slowly transferred to the collector device 199 initially by the first monitoring device 107 and the speed increases until it becomes rapid over a short period of time.

In one embodiment, the collector device 119 asynchronously gathers energy consumption data from the first monitoring device 107 and the second monitoring device 109, incorporates a timestamp into the energy consumption data, and stores it locally until it subsequently transfers it over the Internet to the server 113 employing an appropriate format.

In one embodiment, the monitoring system 105 is capable of monitoring electrical energy consumption, natural gas consumption as well as water consumption in the. For example, it employs the second monitoring device 109 between a natural gas connector (not shown) and the second appliance 153 (that uses natural gas) while being electrically coupled to the second appliance 153. In this case, the collector device 199 obtains a natural gas consumption data from the second monitoring device 153. In addition, a third monitoring device (not shown) that is employed between a water connection and a third appliance (not shown), facilitates monitoring, by the third monitoring device, of water consumption by the third appliance that consumes water. Thus, the collector device 199 obtains a water consumption data from the third monitoring device and the monitoring system 105 is therefore capable of monitoring consumption of water and natural gas.

In general, the collector device 199 obtains a reference time from the remote server 113 and employs the reference time to record the energy consumption data, the water consumption data and the natural gas consumption data. It uploads the collected data to the remote server 113 wherein the collected data comprises a latest readings from one or more monitoring devices 107, 109. In addition, a set of readings can be collected and subsequently communicated to the server 113. For example, the collector device 199 may contain the latest readings from the first monitoring device 107 or a set of recent readings received from the first monitoring device 107, and communicate them to the server 113.

The monitoring system facilitates sending commands to the collector device 199, which are later communicated to the monitoring devices 107, 109, as appropriate. For example, the collector device 199 communicates commands to the first monitoring device 107 based on rules, wherein commands are executed by the first monitoring device 107 resulting in power management of the first electrical appliance 151.

Communication between the collector device 199 and the server 113 may occur over a network 117 that is always available or over a version of the network 117 that is available frequently or periodically. Thus, the collector device 199 is either communicatively coupled constantly with the server 113 and the server 113 pushes commands to the collector device 199 when necessary, or the collector device 199 polls the server 113 for commands while uploading the energy consumption data to the server 113 when it determines that the server 113 is available.

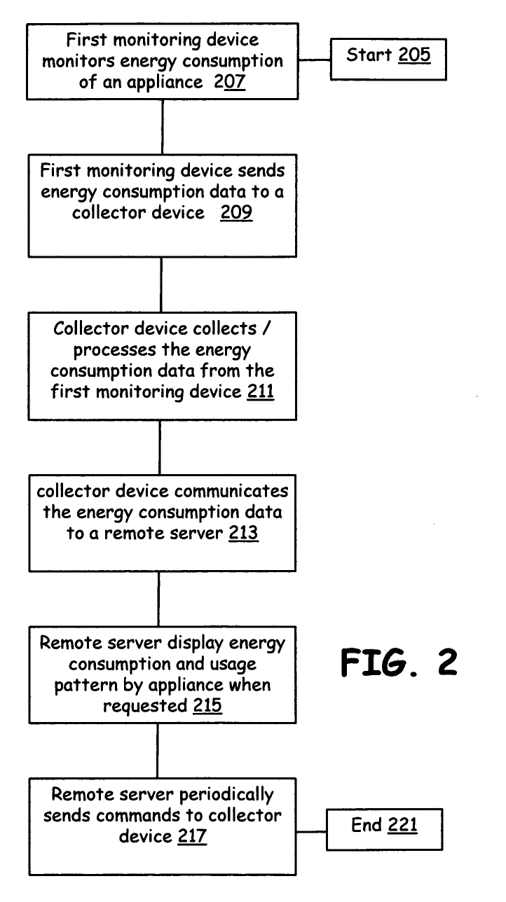

FIG. 2 is a method of operating the monitoring system for collection and distribution of power consumption information wherein the collector device 199 monitors energy consumption by individual electrical appliances 151, 153 employing the monitoring devices 107, 109 for monitoring purposes. At a start block 205, the operation starts when the monitoring devices, such as the first monitoring device 107, are plugged into power sockets in a premises, such as a residence, selectively after initial configuration. For example, the first monitoring device 107 is installed between a power socket and a first electrical appliance after such initial configuration.

Then, at a next block 207, the first monitoring device 107 monitors energy consumption by an appliance that is plugged into it, such as the first electrical appliance 151. It collects an energy consumption data. Then, at a next block 209, the first monitoring device 107 sends the energy consumption data collected to the collector device 199.

Then, at a next block 211, the collector device 199 collects and processes the energy consumption data sent by the first monitoring device and by other monitoring devices. In general, the collector device is communicatively and electrically coupled to the first monitoring device, such as over a powerline 111.

At a next block 213, the collector device 199 communicates the energy consumption data to a remote server communicatively coupled to the collector device. Such communicative coupling is over Internet typically although other types of networks are also contemplated. Then, at a next block 215, the remote server displays the energy consumption data and the usage pattern by appliance, when requested by a user or a reporting system. Other types of usage information based on time of day, power load, etc. are also displayed when requested. At a next block 217, the remote server periodically sends commands to the collector device 199 in order to manage collection of power consumption data from the first appliance 151 via the first monitoring device 107, etc. The collector device 199 receives the commands and sends them to the first monitoring device, as necessary. The operation finally terminates at an end block 221.

Thus, the method facilitates monitoring of energy consumed by the first electrical appliance by the first monitoring device 107 and its communication it to the collector device 199 over an electrically and communicatively coupled communication means. The collector device 199 selectively processes it locally, before communicating it to the remote server for storage and optional display when required.

In one embodiment, the transferring of commands at the block 217, to the collector device 199, is followed by processing of appropriate rules to determine if those commands should then be forwarded to the first monitoring device 107. Thus, commands are sent to the first monitoring device based on processing of rules available. The subsequent execution of the commands, by the first monitoring device 107, results in power management of the first electrical appliance 151.

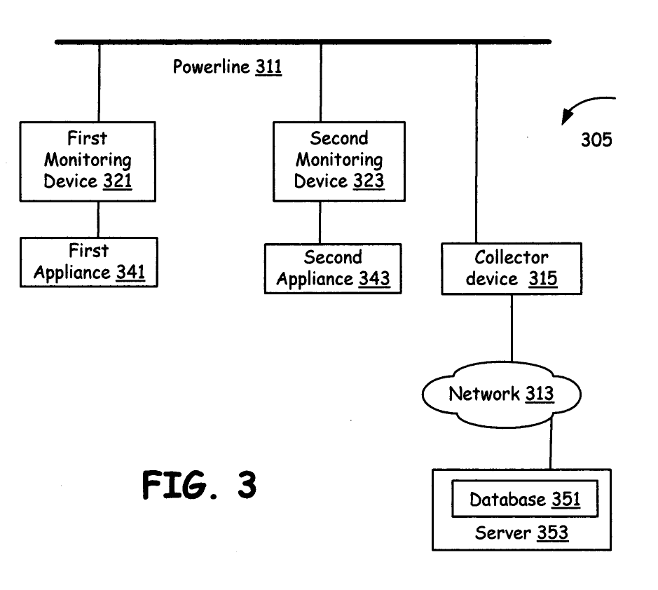

FIG. 3 is an exemplary system 305 for monitoring and reporting power consumption within a premises. The system 305 comprises a plurality of monitoring devices 321, 323, each connected to a monitored appliance 341, 343 respectively. It also comprises the collector device capable of communicating with a server 353 over a network 313. The plurality of monitoring devices 321, 323 are communicatively coupled to the collector device 315 over a powerline 311 that provides power to each of the appliances 341 and 343 via an associated monitoring device.

Each of the plurality of electrical appliances 341, 343 are capable of being electrically coupled to one of the plurality of monitoring devices 321, 323. Each of the plurality of monitoring devices 321, 323 is employed to monitor power consumption by at least one of the plurality of electrical appliances 341, 343. For example, the first monitoring device 321 is plugged into the powerline 311 and the first appliance 341 is plugged into (or otherwise electrically connected to) the first monitoring device 321.

The plurality of monitoring devices 321, 323 are communicatively and electrically coupled to the collector device 315. They monitor the power consumption by a corresponding one of the plurality of electrical appliances 341, 343. Each of the plurality of monitoring devices 321, 323 report the power consumed by the corresponding one of the plurality of electrical appliances 341, 343 to the collector device 315. The power consumed by each of plurality of electrical appliances 341, 343 is managed by a corresponding one of the plurality of monitoring devices 321, 323 with which it is electrically coupled. In one embodiment, each of plurality of electrical appliances 341, 343 is also communicatively coupled to a corresponding one of the plurality of monitoring devices 321, 323 with which it is electrically coupled. In one embodiment, the collector device 315 causes at least one of the plurality of monitoring devices 321, 323 to selectively turn-on or turn-off power to an associated one of the plurality of electrical appliances 341, 343.

The server 353 comprises a database 351 that it employs to store power consumption data by user, by appliance, etc. The server 353 communicates commands to the collector device 315 to manage the plurality of electrical appliances 341, 343 and to gather a power consumption data from each of the plurality of electrical appliances 341, 343.

In one embodiment, the system also comprises a display module that is communicatively coupled to the collector device 315. The collector device 315 employs the display module to present at least the power consumption data received from each of the plurality of electrical appliances 341, 343. In a related embodiment, the display module is integrated into the collector device 315. In another embodiment, it is integrated into the first monitoring device 321.

In one embodiment, the system 305 also includes the capability of verifying the authorization of a user to manage the power consumed by the electrical appliances 341, 343. User authorizations are supported by the server 353, and it ensure that only authorized users can manage the monitoring devices 321, 323, and, through them, the electrical appliances 341, 343.

Although the first monitoring device 321 and the second monitoring device 323 are shown to be directly connected to the powerline 311, it should be clear that appropriate power sockets and power connectors are used in some specific embodiments. Thus, for example, the first monitoring device 321 is connected to the powerline 311 by means of a power connector provided to the first monitoring device 321 that plugs into a power socket associated with and disposed on the powerline 311. Similarly, the collector device 315 is connected to the powerline with the use of a power connector and a corresponding power socket.

As one of ordinary skill in the art will appreciate, the terms “operably coupled” and “communicatively coupled,” as may be used herein, include direct coupling and indirect coupling via another component, element, circuit, or module where, for indirect coupling, the intervening component, element, circuit, or module does not modify the information of a signal but may adjust its current level, voltage level, and/or power level. As one of ordinary skill in the art will also appreciate, inferred coupling (i.e., where one element is coupled to another element by inference) includes direct and indirect coupling between two elements in the same manner as “operably coupled” and “communicatively coupled.”

The present invention has also been described above with the aid of method steps illustrating the performance of specified functions and relationships thereof. The boundaries and sequence of these functional building blocks and method steps have been arbitrarily defined herein for convenience of description. Alternate boundaries and sequences can be defined so long as the specified functions and relationships are appropriately performed. Any such alternate boundaries or sequences are thus within the scope and spirit of the claimed invention.

The present invention has been described above with the aid of functional building blocks illustrating the performance of certain significant functions. The boundaries of these functional building blocks have been arbitrarily defined for convenience of description. Alternate boundaries could be defined as long as the certain significant functions are appropriately performed. Similarly, flow diagram blocks may also have been arbitrarily defined herein to illustrate certain significant functionality. To the extent used, the flow diagram block boundaries and sequence could have been defined otherwise and still perform the certain significant functionality. Such alternate definitions of both functional building blocks and flow diagram blocks and sequences are thus within the scope and spirit of the claimed invention.

One of average skill in the art will also recognize that the functional building blocks, and other illustrative blocks, modules and components herein, can be implemented as illustrated or by discrete components, application specific integrated circuits, processors executing appropriate software and the like or any combination thereof.

Moreover, although described in detail for purposes of clarity and understanding by way of the aforementioned embodiments, the present invention is not limited to such embodiments. It will be obvious to one of average skill in the art that various changes and modifications may be practiced within the spirit and scope of the invention, as limited only by the scope of the appended claims.

What is claimed is:

1. A monitoring system for collection and distribution of a power consumption information, the monitoring system comprising:
a first monitoring device that is employed between, and electrically coupled to, a power socket and a first electrical appliance;
a collector device that collects an energy consumption data from the first monitoring device and communicates it to a remote server;
the first monitoring device monitoring the energy consumption by the first electrical appliance and communicating the energy consumption data to the collector device over a first communication means; and
the collector device processing the energy consumption data and subsequently communicating it to the remote server.

2. The monitoring system of claim 1 wherein the first communication means is a power line to which both the first monitoring device and the collector device are communicatively and electrically coupled.

3. The monitoring system of claim 1 wherein the first monitoring device comprises a relay to cut power consumed by the first electrical appliance.

4. The monitoring system of claim 2 wherein the first monitoring device starts out sending data rapidly to the collector device and then taper off as a quiescent state is reached.

5. The monitoring system of claim 4 wherein, when an event occurs, the first monitoring device starts communicating data to the collector device rapidly initially and then tapering off after reaching a steady state.

6. The monitoring system of claim 2 wherein the collector device asynchronously gathers energy consumption data and stores it locally until it subsequently transfers it over the internet to a server employing an appropriate format.

7. The monitoring system of claim 6 wherein the collector device asynchronously gathers energy consumption data, incorporates a timestamp, and stores it locally until it subsequently transfers it over the Internet to a server employing an appropriate format.

8. The monitoring system of claim 7 further comprising:
a second monitoring device that is employed between a natural gas connector and a second appliance while being electrically coupled to the second appliance;
the collector device obtaining a natural gas consumption data from the second monitoring device;
a third monitoring device that is employed between a water connection and a third appliance while being electrically coupled to the third appliance;
the collector device obtaining a water consumption data from the third monitoring device;
the monitoring system being capable of monitoring consumption of water and natural gas; and
the collector device obtaining a reference time from the remote server and employing the reference time to record the energy consumption data, the water consumption data and the natural gas consumption data.

9. The monitoring system of claim 5 wherein the collector device uploads collected data to the remote server wherein the collected data comprises a latest reading from the first monitoring device or a collection of a set of recent readings received from the first monitoring device.

10. The monitoring system of claim 2 wherein the collector device communicates commands to the first monitoring device based on rules, wherein commands are executed by the first monitoring device resulting in power management of the first appliance.

11. The monitoring system of claim 10 wherein the collector is either communicatively coupled constantly with the remote server and the remote server pushes commands or the collector polls the remote server for commands while uploading the energy consumption data to the remote server.

12. A method of operating a monitoring system for collection and distribution of power consumption information, the method comprising:
monitoring energy consumption and creation of an energy consumption data by a first monitoring device that is installed between a power socket and a first electrical appliance;
sending the energy consumption data by the first monitoring device to a collector device communicatively and electrically coupled to the first monitoring device;
collection, by the collector device, the energy consumption data from the first monitoring device; and
communicating the energy consumption data by the collector device to a remote server communicatively coupled to the collector device.

13. The method of claim 12 wherein the first monitoring device monitors the energy consumption by the first electrical appliance and communicates it to the collector device over an electrically and communicatively coupled communication means.

14. The method of claim 13 further comprising:
processing of the energy consumption data locally, by the collector device, before communicating it to the remote server.

15. The method of claim 13 further comprising:
transferring commands, by the collector device, to the first monitoring device based on rules; and
executing the commands, by the first monitoring device, that results in power management of the first appliance.

16. A system for monitoring and reporting power consumption within a premises, the system comprising:
a collector device capable of communicating with a remote server;
a plurality of monitoring devices;
a plurality of electrical appliances, each capable of being electrically coupled to one of the plurality of monitoring devices;
the plurality of monitoring devices wherein each of the plurality of monitoring devices is employed to monitor power consumption by at least one of the plurality of electrical appliances;
the plurality of monitoring devices communicatively and electrically coupled to the collector device;
the plurality of monitoring devices monitoring the power consumption by a corresponding one of the plurality of electrical appliances; and
each of the plurality of monitoring devices reporting the power consumed by the corresponding one of the plurality of electrical appliances to the collector device.

17. The system of claim 16 wherein the power consumed by each of plurality of electrical appliances is managed by a corresponding one of the plurality of monitoring devices with which it is electrically coupled.

18. The system of claim 16 wherein the remote server communicates commands to the collector device to manage the plurality of electrical appliances and to gather a power consumption data from each of the plurality of electrical appliances.

19. The system of claim 18 further comprising:
a display module; and
the collector device employing the display module to present at least the power consumption data received from each of the plurality of electrical appliances.

20. The system of claim 16 wherein the collector device causes at least one of the plurality of monitoring devices to turn off power to an associated one of the plurality of electrical appliances.
